(19) United States
(12) Patent Application Publication
(10) Pub. No.: US 2013/0019948 A1
(43) Pub. Date: Jan. 24, 2013

(54) STABILIZED BACK CONTACT FOR PHOTOVOLTAIC DEVICES AND METHODS OF THEIR MANUFACTURE

(71) Applicant: Scott Daniel Feldman-Peabody, Golden, CO (US)

(72) Inventor: Scott Daniel Feldman-Peabody, Golden, CO (US)

(73) Assignee: PRIMESTAR SOLAR, INC., Arvada, CO (US)

(21) Appl. No.: 13/188,808

(22) Filed: Jul. 22, 2011

(51) Int. Cl. H01L 31/0264; H01L 31/18

(52) U.S. Cl. 136/260; 438/95; 257/E31.015

(57) ABSTRACT

Thin film photovoltaic devices including a thin film stabilization layer between the photovoltaic heterojunction and a back contact are provided. The thin film stabilization layer generally includes cadmium sulfide, but may also include copper and/or other materials. Methods are also provided for forming a thin film photovoltaic device via forming a thin film stabilization layer on a photovoltaic heterojunction (that generally overlies a transparent conductive oxide layer on a transparent substrate) and forming a back contact on the thin film stabilization layer.

### FIELD OF THE INVENTION

The subject matter disclosed herein relates generally to a stabilized back contact for use in a photovoltaic device, along with their methods of deposition. More particularly, the subject matter disclosed herein relates to a CdS stabilized back contact layer for use in cadmium telluride thin film photovoltaic devices and their methods of manufacture.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. For example, CdTe has an energy bandgap of about 1.45 eV, which enables it to convert more energy from the solar spectrum as compared to lower bandgap semiconductor materials historically used in solar cell applications (e.g., about 1.1 eV for silicon). Also, CdTe converts radiation energy in lower or diffuse light conditions as compared to the lower bandgap materials and, thus, has a longer effective conversion time over the course of a day or in cloudy conditions as compared to other conventional materials. The junction of the n-type layer and the p-type layer is generally responsible for the generation of electric potential and electric current when the CdTe PV module is exposed to light energy, such as sunlight. Specifically, the cadmium telluride (CdTe) layer and the cadmium sulfide (CdS) form a p-n heterojunction, where the CdTe layer acts as a p-type layer (i.e., an electron accepting layer or absorber layer) and the CdS layer acts as a n-type layer (i.e., a electron donating layer or a window layer).

A transparent conductive oxide (“TCO”) layer is commonly used between the window glass and the junction forming layers. This TCO layer provides the front electrical contact on one side of the device and is used to collect and carry the electrical charge produced by the cell. Conversely, a back contact layer is provided on the opposite side of the junction forming layers and is used as the opposite contact of the cell. This back contact layer is adjacent to the p-type layer, such as the cadmium telluride layer in a CdTe PV device.

The cadmium telluride layer is typically doped with copper in a CdTe PV device. However, diffusion and/or electro-migration can lead to degradation of the CdTe PV device over time, especially as the copper atoms migrate away from the interface of the cadmium telluride layer and the back contact, potentially leading to significantly reduced energy conversion efficiency in the device.

Thus, a need exists for photovoltaic devices having improved stability of energy conversion efficiency and/or device lifetime through improved stability of the contact between the back contact and the p-type absorber layer, particularly when the p-type absorber layer includes cadmium telluride.

### BRIEF DESCRIPTION OF THE INVENTION

Aspects and advantages of the invention will be set forth in part in the following description, or may be obvious from the description, or may be learned through practice of the invention.

Thin film photovoltaic devices are generally provided that include a glass substrate, a transparent conductive oxide layer on the glass substrate, a photovoltaic heterojunction (e.g., formed from an absorber layer that includes cadmium telluride and a window layer that includes cadmium sulfide) on the transparent conductive oxide layer, a thin film stabilization layer on the photovoltaic heterojunction, and a back contact on the thin film stabilization layer. In one particular embodiment, the thin film stabilization layer generally can have a greater affinity for copper than the absorber layer of the photovoltaic heterojunction. For example, the thin film stabilization layer can generally include, in one particular embodiment, cadmium sulfide, but may also include copper, oxygen, and/or other materials.

Methods are also generally provided for forming a thin film photovoltaic device via forming a thin film stabilization layer on a photovoltaic heterojunction (that generally overlies a transparent conductive oxide layer on a glass substrate) and forming a back contact on the thin film stabilization layer. The thin film stabilization layer generally comprises cadmium sulfide. The photovoltaic heterojunction can, in certain embodiments, be treated with cadmium chloride and/or doped with copper before or after forming the thin film stabilization layer.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a general schematic of a cross-sectional view of an exemplary cadmium telluride thin film photovoltaic device including a thin film stabilization layer;

FIG. 2 shows a flow diagram of an exemplary method of manufacturing a thin film photovoltaic device;

FIG. 3 shows a flow diagram of another exemplary method of manufacturing a thin film photovoltaic device; and,

FIG. 4 shows a flow diagram of yet another exemplary method of manufacturing a thin film photovoltaic device.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers, unless expressly stated to the contrary. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

In general, photovoltaic devices are presently disclosed having a thin film stabilization layer between the photovoltaic heterojunction and the back contact layer(s). This configuration is particularly useful when the photovoltaic heterojunction is formed using an absorber layer (i.e., a p-type layer) that includes cadmium telluride. For example, the thin film stabilization layer can be utilized between the p-type layer (e.g., an absorber layer including cadmium telluride; commonly referred to as a “cadmium telluride layer”) and the metal contact layer. As such, in one particular embodiment, the thin film photovoltaic device can include a cadmium telluride layer as the p-type layer and directly contact the thin film stabilization layer. The thin film stabilization layer can generally provide improved stability between a cadmium telluride layer and the back electrical contact.

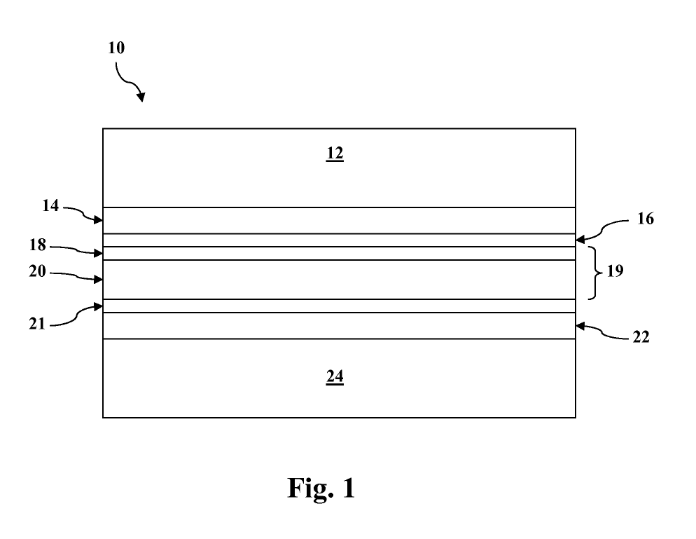

FIG. 1 shows a cross-section of an exemplary thin-film photovoltaic device 10. The device 10 is shown including a transparent substrate 12 (e.g., a glass substrate), a transparent conductive oxide (TCO) layer 14, a resistive transparent buffer layer 16, an n-type window layer 18 (e.g., including cadmium sulfide), an absorber layer 20 (e.g., including cadmium telluride), a thin film stabilization layer 21, a back contact 22, and an encapsulating glass. 24.

As stated, the thin film stabilization layer 21 generally improves the stability between the absorber layer 20 and the back contact 22. When the absorber layer 20 includes cadmium telluride (also referred to as a cadmium telluride layer 20), the thin film stabilization layer 21 can have a greater affinity for copper than cadmium telluride (e.g., the thin film stabilization layer 21 can include cadmium sulfide). As such, upon treatment of the cadmium telluride layer 20 with copper (e.g., copper chloride), the copper concentration can be greater in the thin film stabilization layer 21 than in the cadmium telluride layer 20, at least at the interface of the cadmium telluride layer 20 and the thin film layer 21. Thus, such a thin film stabilization layer 21 can serve as a copper “sink” and can aid in the retention of copper at the back of the cadmium telluride layer 20 over time to help maintain a sufficient electrical contact between the cadmium telluride layer 20 and the back contact layer 22, which can lead to improved device stability. Furthermore, this copper retention aspect of the thin film stabilization layer 21 can help to moderate the level of copper at the junction and/or in the window layers, where too much copper could cause a loss in performance of the device.

Although shown and described as a cadmium telluride thin film photovoltaic device 10 in FIG. 1, the thin film stabilization layer 21 can be included in any type of thin film photovoltaic device, especially those that use an absorber layer that includes cadmium telluride.

As stated, FIG. 1 represents an exemplary cadmium telluride thin film photovoltaic device 10 having a thin film stabilization layer 21 positioned between back contact 22 and the photovoltaic heterojunction 19 formed from the cadmium sulfide layer 18 and the cadmium telluride layer 20. In the embodiments shown, the thin film stabilization layer 21 is in direct contact with the cadmium telluride layer 20 and the back contact 22 to maximize electrical conduction therebetween. However, in certain embodiments, intermediate layers may be positioned between the cadmium telluride layer 20 and the thin film stabilization layer 21 and/or the back contact layer 22 and the thin film stabilization layer 21. For example, a metal-telluride layer (not shown) can be included between the cadmium telluride layer 20 and the thin film stabilization layer 21 (e.g., where the metal includes copper, zinc, magnesium, manganese, antimony, arsenic, or combinations thereof).

The thin film stabilization layer 21, as deposited, can be a material that has a greater affinity for copper than the absorber layer 20. For example, when the absorber layer 20 includes cadmium telluride, the thin film stabilization layer 21 can include cadmium sulfide. In this embodiment, upon treatment with copper, copper atoms can be preferentially retained by the thin film stabilization layer 21, reducing their tendency to migrate to the absorber layer 20 that includes cadmium telluride. Other materials may also be present in the thin film stabilization layer 21, such as copper, gold, palladium, platinum, indium, aluminum, gallium, chlorine, fluorine, oxygen, nitrogen, or mixtures thereof. For instance, the thin film stabilization layer 21 can include, in one embodiment, a copper-doped cadmium sulfide material.

The thin film stabilization layer 21 can be a relatively thin film layer, such as having a thickness of about 5 nm to about 25 nm (e.g., about 7 nm to about 15 nm). Such a relatively thin layer can help ensure sufficient electrical conduction therethrough between the absorber layer 20 and the back contact layer 22.

Depositing the thin film stabilization layer 21 can be achieved through any suitable process, including but not limited to, sputtering, chemical vapor deposition, spray pyrolysis, chemical bath deposition, or any other suitable deposition method. In one particular embodiment, when the thin film stabilization layer 21 is deposited to be substantially free from oxygen, the thin film stabilization layer 21 can be sputtered from a target in an inert atmosphere (e.g., argon) that is substantially free from oxygen. For instance, the target can include cadmium sulfide. In another embodiment, the thin film stabilization layer 21 can be deposited with some content of oxygen, such as about 1% to about 25% by weight (e.g., about 5% to about 10% by weight). For instance, the thin film stabilization layer 21 can be sputtered from a target (e.g., of cadmium sulfide) in a sputtering atmosphere that includes oxygen (e.g., about 1 to about 30% by volume).

As stated, a thin film stabilization layer 21 that includes cadmium sulfide can be particularly useful in conjunction with a cadmium telluride layer 20 that has been copper treated (e.g., that includes copper-doping). The cadmium telluride layer 20 can be treated with copper before or after the formation of the thin film stabilization layer 21 on the cadmium telluride layer 20. Additionally, the cadmium telluride layer 20 can be treated with cadmium chloride, either before and/or after the formation of the thin film stabilization layer 21 on the cadmium telluride layer 20.

As stated, the thin film stabilization layer 21 is particularly useful for inclusion in the exemplary cadmium telluride based thin film photovoltaic device 10 shown in FIG. 1. As stated, the device 10 includes a glass substrate 12 employed as the substrate. In these embodiments, the glass substrate 12 can be referred to as a “superstrate”, as it is the substrate on which the subsequent layers are formed even though it faces upward to the radiation source (e.g., the sun) when the photovoltaic device 10 is in use. The glass substrate 12 can be a high-transmission glass (e.g., high transmission borosilicate glass), low-iron float glass, or other highly transparent glass material. The glass is generally thick enough to provide support for the subsequent film layers (e.g., from about 0.5 mm to about 10 mm thick), and is substantially flat to provide a good surface for forming the subsequent film layers. In one embodiment, the glass substrate 12 can be a low iron float glass containing less than about 0.15% by weight iron (Fe), and may have a transmissiveness of about 0.9 or greater in the spectrum of interest (e.g., wavelengths from about 300 nm to about 900 nm).

Generally, the TCO layer 14 is shown on the glass substrate 12 of the exemplary device 10. The TCO layer 14 allows light to pass through with minimal absorption while also allowing electric current produced by the device 10 to travel sideways to opaque metal conductors (not shown). For instance, the TCO layer 14 can have a sheet resistance less than about 30 ohm per square, such as from about 4 ohm per square to about 20 ohm per square (e.g., from about 8 ohm per square to about 15 ohm per square). The TCO layer 14 generally includes at least one conductive oxide, such as tin oxide, zinc oxide, indium tin oxide, zinc stannate, cadmium stannate, or mixtures thereof. Additionally, the TCO layer 14 can include other conductive, transparent materials. The TCO layer 14 can also include dopants (e.g., fluorine, tin, etc.) and other materials, as desired.

The TCO layer 14 can be formed by sputtering, chemical vapor deposition, spray pyrolysis, or any other suitable deposition method. In one particular embodiment, the TCO layer 14 can be formed by sputtering (e.g., DC sputtering or RF sputtering) on the glass substrate 12. For example, a cadmium stannate layer can be formed by sputtering a hot-pressed target containing stoichiometric amounts of SnO₂ and CdO onto the glass substrate 12 in a ratio of about 1 to about 2. The cadmium stannate can alternatively be prepared by using cadmium acetate and tin (II) chloride precursors by spray pyrolysis. In certain embodiments, the TCO layer 14 can have a thickness between about 0.1 μm and about 1 μm, for example from about 0.1 μm to about 0.5 μm, such as from about 0.25 μm to about 0.35 μm.

A resistive transparent buffer layer 16 (RTB layer) is shown on the TCO layer 14 on the exemplary photovoltaic devices 10. The RTB layer 16 is generally more resistive than the TCO layer 14 and can help protect the device 10 from chemical interactions between the TCO layer 14 and the subsequent layers during processing of the device 10. For example, in certain embodiments, the RTB layer 16 can have a sheet resistance that is greater than about 1000 ohms per square, such as from about 10 kOhms per square to about 1000 MOhms per square. The RTB layer 16 can also have a wide optical bandgap (e.g., greater than about 2.5 eV, such as from about 2.7 eV to about 3.5 eV).

Without wishing to be bound by a particular theory, it is believed that the presence of the RTB layer 16 between the TCO layer 14 and the cadmium sulfide layer 18 can allow for a relatively thin cadmium sulfide layer 18 to be included in the device 10 by reducing the possibility of interface defects (i.e., “pinholes” in the cadmium sulfide layer 18) creating shunts between the TCO layer 14 and the cadmium telluride layer 20. Thus, it is believed that the RTB layer 16 allows for improved adhesion and/or interaction between the TCO layer 14 and the cadmium telluride layer 20, thereby allowing a relatively thin cadmium sulfide layer 18 to be formed thereon without significant adverse effects that would otherwise result from such a relatively thin cadmium sulfide layer 18 formed directly on the TCO layer 14.

The RTB layer 16 can include, for instance, a combination of zinc oxide (ZnO) and tin oxide (SnO₂), which can be referred to as a zinc tin oxide layer (“ZTO”). In one particular embodiment, the RTB layer 16 can include more tin oxide than zinc oxide. For example, the RTB layer 16 can have a composition with a stoichiometric ratio of ZnO/SnO₂ between about 0.25 and about 3, such as in about an one to two (1:2) stoichiometric ratio of tin oxide to zinc oxide. The RTB layer 16 can be formed by sputtering, chemical vapor deposition, spray-pyrolysis, or any other suitable deposition method. In one particular embodiment, the RTB layer 16 can be formed by sputtering (e.g., DC sputtering or RF sputtering) on the TCO layer 14. For example, the RTB layer 16 can be deposited using a DC sputtering method by applying a DC current to a metallic source material (e.g., elemental zinc, elemental tin, or a mixture thereof) and sputtering the metallic source material onto the TCO layer 14 in the presence of an oxidizing atmosphere (e.g., O₂ gas). When the oxidizing atmosphere includes oxygen gas (i.e., O₂), the atmosphere can be greater than about 95% pure oxygen, such as greater than about 99%.

In certain embodiments, the RTB layer 16 can have a thickness between about 0.075 μm and about 1 μm, for example from about 0.1 μm to about 0.5 μm. In particular embodiments, the RTB layer 16 can have a thickness between about 0.08 μm and about 0.2 μm, for example from about 0.1 μm to about 0.15 μm.

A cadmium sulfide layer 18 is shown on RTB layer 16 of the exemplary device 10. The cadmium sulfide layer 18 is a n-type layer that generally includes cadmium sulfide (CdS) but may also include other materials, such as zinc sulfide, cadmium zinc sulfide, etc., and mixtures thereof as well as dopants and other impurities. In one particular embodiment, the cadmium sulfide layer may include oxygen up to about 25% by atomic percentage, for example from about 5% to about 20% by atomic percentage. The cadmium sulfide layer 18 can have a wide band gap (e.g., from about 2.25 eV to about 2.5 eV, such as about 2.4 eV) in order to allow most radiation energy (e.g., solar radiation) to pass. As such, the cadmium sulfide layer 18 is considered a transparent layer on the device 10.

The cadmium sulfide layer 18 can be formed by sputtering, chemical vapor deposition, chemical bath deposition, and other suitable deposition methods. In one particular embodiment, the cadmium sulfide layer 18 can be formed by sputtering (e.g., direct current (DC) sputtering or radio frequency (RF) sputtering) on the RTB layer 16. Sputtering deposition generally involves ejecting material from a target, which is the material source, and depositing the ejected material onto the substrate to form the film. DC sputtering generally involves applying a current to a metal target (i.e., the cathode) positioned near the substrate (i.e., the anode) within a sputtering chamber to form a direct-current discharge. The sputtering chamber can have a reactive atmosphere (e.g., an oxygen atmosphere, nitrogen atmosphere, fluorine atmosphere) that forms a plasma field between the metal target and the substrate. The pressure of the reactive atmosphere can be between about 1 mTorr and about 20 mTorr for magnetron sputtering. When metal atoms are released from the target upon application of the voltage, the metal atoms can react with the plasma and deposit onto the surface of the substrate. For example, when the atmosphere contains oxygen, the metal atoms released from the metal target can form a metallic oxide layer on the substrate. The current applied to the source material can vary depending on the size of the source material, size of the sputtering chamber, amount of surface area of substrate, and other variables. In some embodiments, the current applied can be from about 2 amps to about 20 amps. Conversely, RF sputtering generally involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere) having a pressure between about 1 mTorr and about 20 mTorr.

Due to the presence of the RTB layer 16, the cadmium sulfide layer 18 can have a thickness that is less than about 0.1 μm, such as between about 10 nm and about 100 nm, such as from about 50 nm to about 80 nm, with a minimal presence of pinholes between the TCO layer 14 and the cadmium sulfide layer 18. Additionally, a cadmium sulfide layer 18 having a thickness less than about 0.1 μm reduces any absorption of radiation energy by the cadmium sulfide layer 18, effectively increasing the amount of radiation energy reaching the underlying cadmium telluride layer 20.

A cadmium telluride layer 20 is shown on the cadmium sulfide layer 18 in the exemplary devices 10. The cadmium telluride layer 20 is a p-type layer that generally includes cadmium telluride (CdTe) but may also include other materials. As the p-type layer of device 10, the cadmium telluride layer 20 is the photovoltaic layer that interacts with the cadmium sulfide layer 18 (i.e., the n-type layer) to produce current from the adsorption of radiation energy by absorbing the majority of the radiation energy passing into the device 10 due to its high absorption coefficient and creating electron-hole pairs. For example, the cadmium telluride layer 20 can generally be formed from cadmium telluride and can have a bandgap tailored to absorb radiation energy (e.g., from about 1.4 eV to about 1.5 eV, such as about 1.45 eV) to create the maximum number of electron-hole pairs with the highest electrical potential (voltage) upon absorption of the radiation energy. Electrons may travel from the p-type side (i.e., the cadmium telluride layer 20) across the junction to the n-type side (i.e., the cadmium sulfide layer 18) and, conversely, holes may pass from the n-type side to the p-type side. Thus, the p-n junction formed between the cadmium sulfide layer 18 and the cadmium telluride layer 20 forms a diode in which the charge imbalance leads to the creation of an electric field spanning the p-n junction. Conventional current is allowed to flow in only one direction and separates the light induced electron-hole pairs.

The cadmium telluride layer 20 can be formed by any known process, such as vapor transport deposition, chemical vapor deposition (CVD), spray pyrolysis, electro-deposition, sputtering, close-space sublimation (CSS), etc. In one particular embodiment, the cadmium sulfide layer 18 is deposited by sputtering and the cadmium telluride layer 20 is deposited by close-space sublimation. In particular embodiments, the cadmium telluride layer 20 can have a thickness between about 0.1 μm and about 10 μm, such as from about 1 μm and about 5 μm. In one particular embodiment, the cadmium telluride layer 20 can have a thickness between about 1.5 μm and about 4 μm, such as about 2 μm to about 3 μm.

A series of post-forming treatments can be applied to the exposed surface of the cadmium telluride layer 20. These treatments can tailor the functionality of the cadmium telluride layer 20 and prepare its surface for subsequent adhesion to the back contact layer(s) 22. For example, the cadmium telluride layer 20 can be annealed at elevated temperatures (e.g., from about 350° C. to about 500° C., such as from about 375° C. to about 425° C.) for a sufficient time (e.g., from about 1 to about 40 minutes) to create a quality p-type layer of cadmium telluride. Without wishing to be bound by theory, it is believed that annealing the cadmium telluride layer 20 (and the device 10) decreases the deep-defect density and makes the CdTe layer more p-type. Additionally, the cadmium telluride layer 20 can recrystallize and undergo grain regrowth during annealing.

Annealing the cadmium telluride layer 20 can be carried out in the presence of cadmium chloride in order to dope the cadmium telluride layer 20 with chloride ions. For example, the cadmium telluride layer 20 can be washed with an aqueous solution containing cadmium chloride then annealed at the elevated temperature (e.g., via heating the photovoltaic heterojunction to a treatment temperature of about 380° C. to about 430° C.).

In one particular embodiment, after annealing the cadmium telluride layer 20 in the presence of cadmium chloride, the surface can be washed to remove any cadmium oxide formed on the surface. This surface preparation can leave a Te-rich surface on the cadmium telluride layer 20 by removing oxides from the surface, such as CdO, CdTeO₃, CdTe₂O₅, etc. For instance, the surface can be washed with a suitable solvent (e.g., ethylenediamine also known as 1,2 diaminoethane or “DAE”) to remove any cadmium oxide from the surface.

Additionally, copper can be added to the cadmium telluride layer 20. Along with a suitable etch, the addition of copper to the cadmium telluride layer 20 can form a surface of copper-telluride on the cadmium telluride layer 20 in order to obtain a low-resistance electrical contact between the cadmium telluride layer 20 (i.e., the p-type layer) and the back contact layer(s). Specifically, the addition of copper can create a surface layer of cuprous telluride (Cu₂Te) between the cadmium telluride layer 20 and the back contact layer 22 and/or can create a Cu-doped CdTe layer. Thus, the Te-rich surface of the cadmium telluride layer 20 can enhance the collection of current created by the device through lower resistivity between the cadmium telluride layer 20 and the back contact layer 22.

Copper can be applied to the exposed surface of the cadmium telluride layer 20 by any process. For example, copper can be sprayed or washed on the surface of the cadmium telluride layer 20 in a solution with a suitable solvent (e.g., methanol, water, or the like, or combinations thereof) followed by annealing. In particular embodiments, the copper may be supplied in the solution in the form of copper chloride, copper iodide, or copper acetate. The annealing temperature is sufficient to allow diffusion of the copper ions into the cadmium telluride layer 20, such as from about 125° C. to about 300° C. (e.g. from about 150° C. to about 250° C.) for about 5 minutes to about 30 minutes, such as from about 10 to about 25 minutes.

As discussed above, a thin film stabilization layer 21 including cadmium sulfide is shown on the cadmium telluride layer 20.

A back contact layer 22 is shown on the thin film stabilization layer 21. The back contact layer 22 generally serves as the back electrical contact, in relation to the opposite, TCO layer 14 serving as the front electrical contact. The back contact layer 22 can be formed on, and in one embodiment is in direct contact with, the thin film stabilization layer 21. The back contact layer 22 is suitably made from one or more highly conductive materials, such as elemental nickel, chromium, copper, tin, silver, or alloys or mixtures thereof. Additionally, the back contact layer 22 can be a single layer or can be a plurality of layers. In one particular embodiment, the back contact layer 22 can include graphite, such as a layer of carbon deposited on the p-layer followed by one or more layers of metal, such as the metals described above. The back contact layer 22, if made of or comprising one or more metals, is suitably applied by a technique such as sputtering or metal evaporation. If it is made from a graphite and polymer blend, or from a carbon paste, the blend or paste is applied to the semiconductor device by any suitable method for spreading the blend or paste, such as screen printing, spraying or by a “doctor” blade. After the application of the graphite blend or carbon paste, the device can be heated to convert the blend or paste into the conductive back contact layer. A carbon layer, if used, can be from about 0.1 μm to about 10 μm in thickness, for example from about 1 μm to about 5 μm. A metal layer of the back contact, if used for or as part of the back contact layer 22, can be from about 0.1 μm to about 1.5 μm in thickness.

The encapsulating glass 24 is also shown in the exemplary cadmium telluride thin film photovoltaic device 10 of FIG. 1.

Other components (not shown) can be included in the exemplary device 10, such as buss bars, external wiring, laser etches, etc. For example, when the device 10 forms a photovoltaic cell of a photovoltaic module, a plurality of photovoltaic cells can be connected in series in order to achieve a desired voltage, such as through an electrical wiring connection. Each end of the series connected cells can be attached to a suitable conductor such as a wire or bus bar, to direct the photovoltaically generated current to convenient locations for connection to a device or other system using the generated electric. A convenient means for achieving such series connections is to laser scribe the device to divide the device into a series of cells connected by interconnects. In one particular embodiment, for instance, a laser can be used to scribe the deposited layers of the semiconductor device to divide the device into a plurality of series connected cells.

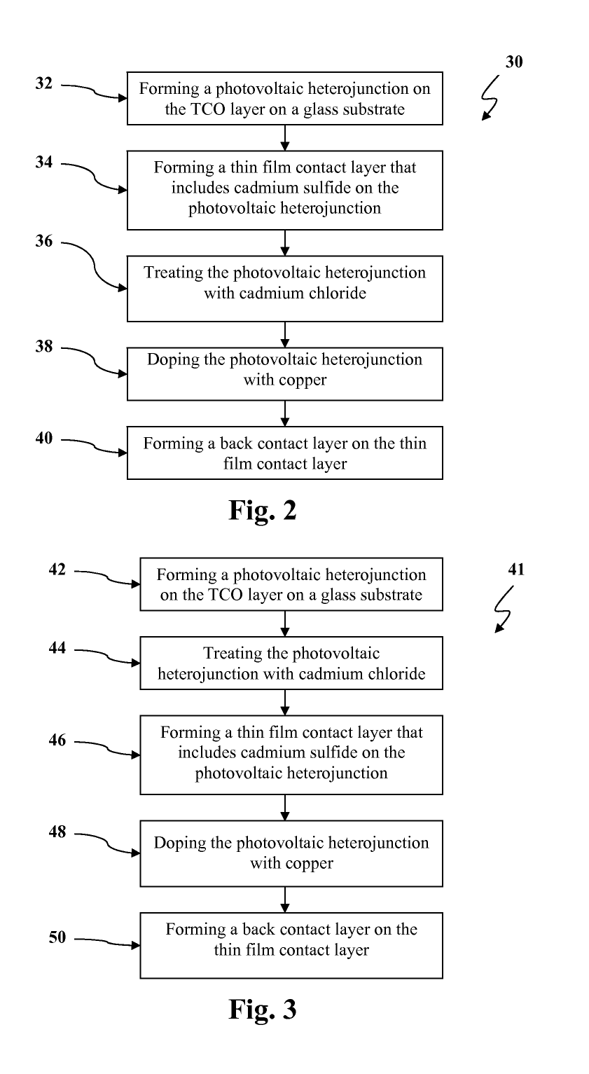

FIG. 2 shows a flow diagram of an exemplary method 30 of manufacturing a photovoltaic device according to one embodiment of the present invention. According to the exemplary method 30, a photovoltaic heterojunction is formed on the TCO layer (optionally, with a RTB layer therebetween) at 32. At 34, a thin film stabilization layer that includes cadmium sulfide is formed on the photovoltaic heterojunction. The photovoltaic heterojunction can then be treated with cadmium chloride at 36 and doped with copper at 38. At 40, a back contact layer(s) can be formed on the photovoltaic heterojunction.

FIG. 3 shows a flow diagram of an alternate method 41 of manufacturing a photovoltaic device according to one embodiment of the present invention. According to the exemplary method 41, a photovoltaic heterojunction is formed on the TCO layer (optionally, with a RTB layer therebetween) at 42. At 44, the photovoltaic heterojunction can then be treated with cadmium chloride. A thin film stabilization layer that includes cadmium sulfide can then be formed on the photovoltaic heterojunction at 46, and doped with copper at 48. At 50, a back contact layer(s) can be formed on the photovoltaic heterojunction.

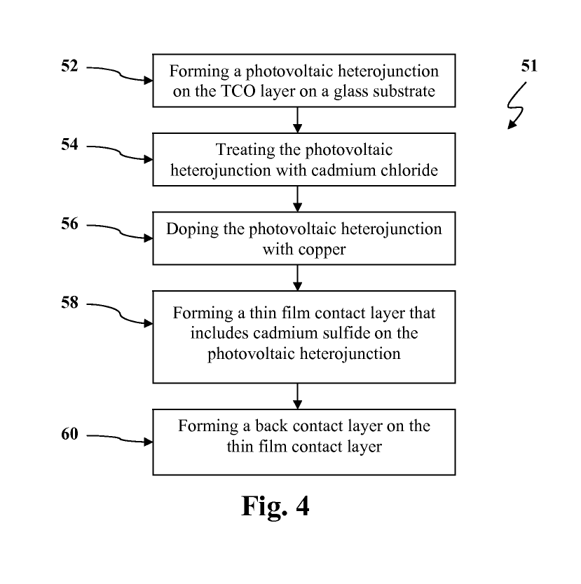

FIG. 4 shows a flow diagram of yet another method 51 of manufacturing a photovoltaic device according to one embodiment of the present invention. According to the exemplary method 51, a photovoltaic heterojunction is formed on the TCO layer (optionally, with a RTB layer therebetween) at 52. At 54, the photovoltaic heterojunction can then be treated with cadmium chloride, and doped with copper at 56. A thin film stabilization layer that includes cadmium sulfide can then be formed on the photovoltaic heterojunction at 58. At 50, a back contact layer(s) can be formed on the thin film stabilization layer.

In one particular embodiment, the photovoltaic heterojunction of any of the methods diagramed in FIGS. 2-4 includes a n-type window layer comprising cadmium sulfide (i.e., a “cadmium sulfide layer” formed on the TCO layer and an absorber layer comprising cadmium telluride (i.e., a “cadmium telluride layer”) formed on the cadmium sulfide layer.

One of ordinary skill in the art should recognize that other processing and/or treatments can be included in the methods 30, 41, and 51. For instance, when including a cadmium sulfide layer and a cadmium telluride layer, the cadmium telluride layer can be annealed in the presence of cadmium chloride, washed to remove any CdO formed on the surface, and doped with copper. Back contact layer(s) can be applied over the cadmium telluride layer, and an encapsulating glass can be applied over the back contact layer. Additionally, the method may also include laser scribing to form electrically isolated photovoltaic cells in the device. These electrically isolated photovoltaic cells can then be connected in series to form a photovoltaic module. Also, electrical wires can be connected to positive and negative terminals of the photovoltaic module to provide lead wires to harness electrical current produced by the photovoltaic module.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A thin film photovoltaic device, comprising:
a transparent substrate;
a transparent conductive oxide layer on the transparent substrate;
a photovoltaic heterojunction on the transparent conductive oxide layer;
a thin film stabilization layer on the photovoltaic heterojunction, wherein the thin film stabilization layer comprises cadmium sulfide; and,
a back contact on the thin film stabilization layer.

2. The device of claim 1, wherein the thin film stabilization layer further comprises copper.

3. The device of claim 1, wherein the thin film stabilization layer further comprises oxygen.

4. The device of claim 1, wherein the thin film stabilization layer has a thickness of about 0.1 nm to about 20 nm.

5. The device of claim 1, wherein the thin film stabilization layer has a thickness of about 1 nm to about 15 nm.

6. The device of claim 1, wherein the photovoltaic heterojunction comprises a cadmium sulfide layer and a cadmium telluride layer, wherein the cadmium sulfide layer is on the transparent conductive oxide layer and the cadmium telluride layer on the cadmium sulfide layer, and wherein the thin film stabilization layer is on the cadmium telluride layer.

7. The device of claim 1, further comprising a resistive transparent oxide layer between the transparent conductive oxide layer and the photovoltaic heterojunction.

8. A thin film photovoltaic device, comprising:
a transparent substrate;
a transparent conductive oxide layer on the transparent substrate;
a photovoltaic heterojunction on the transparent conductive oxide layer, wherein the photovoltaic heterojunction includes a window layer and an absorber layer;
a thin film stabilization layer on the photovoltaic heterojunction, wherein the thin film stabilization layer has a greater affinity for copper than the absorber layer; and,
a back contact on the thin film stabilization layer.

9. The device of claim 8, wherein the absorber layer comprises cadmium telluride.

10. The device of claim 9, wherein the thin film stabilization layer comprises cadmium sulfide.

11. A method of forming a thin film photovoltaic device, the method comprising:
forming a thin film stabilization layer on a photovoltaic heterojunction, wherein the thin film stabilization layer comprises cadmium sulfide, and wherein the photovoltaic heterojunction overlies a transparent conductive oxide layer on a transparent substrate; and,
forming a back contact on the thin film stabilization layer.

12. The method of claim 11, further comprising:
forming the photovoltaic heterojunction on the transparent conductive oxide layer, wherein the photovoltaic heterojunction includes a window layer and an absorber layer, the absorber layer comprising cadmium telluride.

13. The method of claim 11, further comprising:
treating the photovoltaic heterojunction with cadmium chloride.

14. The method of claim 13, wherein the photovoltaic heterojunction is treated with cadmium chloride after forming the forming a thin film stabilization layer on a photovoltaic heterojunction.

15. The method of claim 13, wherein the photovoltaic heterojunction is treated with cadmium chloride prior to forming the back contact on the thin film stabilization layer.

16. The method of claim 13, wherein treating the photovoltaic heterojunction with cadmium chloride comprises:
applying cadmium chloride to the photovoltaic heterojunction; and,
heating the photovoltaic heterojunction to a treatment temperature of about 380° C. to about 430° C.

17. The method of claim 11, further comprising:
doping the photovoltaic heterojunction with copper.

18. The method of claim 17, wherein the photovoltaic heterojunction is doped with copper after forming the thin film stabilization layer on the photovoltaic heterojunction.

19. The method of claim 17, further comprising:
treating the photovoltaic heterojunction with cadmium chloride.

20. The method of claim 19, wherein the thin film stabilization layer is formed on the photovoltaic heterojunction prior to doping the photovoltaic heterojunction with copper and prior to treating the photovoltaic heterojunction with cadmium chloride.
